(19) United States
(12) Patent Application Publication
(10) Pub. No.: US 2019/0103290 A1
(43) Pub. Date: Apr. 4, 2019

(54) THERMAL VAPOR CHAMBER ARRANGEMENT

(71) Applicant: Hewlett Packard Enterprise Development LP, Houston, TX (US)

(72) Inventors: Ernesto Ferrer Medina, Aguadilla, PR (US); Niru Kumari, Palo Alto, CA (US); Chih C. Shih, San Jose, CA (US); Sergio Escobar-Vargas, Santa Clara, CA (US)

(21) Appl. No.: 15/724,251

(22) Filed: Oct. 3, 2017

(51) Int. Cl. H01L 21/48; H01L 23/367; H05K 7/20

(52) U.S. Cl. CPC H01L 21/4882; F28D 15/02; H05K 7/20309; H01L 23/3677

(57) ABSTRACT

In some examples, a multiple chip module (MCM) includes a heat sink; a circuit board; a first chip secured to a first location on the circuit board; a first vapor chamber thermally coupled to the first chip to pass heat generated by the first chip to the heat sink; a second chip secured to a second location on the circuit board; and a second vapor chamber thermally coupled to the second chip to pass heat generated by the second chip to the heat sink. In some examples, a portion of the second vapor chamber is positioned between a portion of the first vapor chamber and the heat sink. In some examples, the first vapor chamber is substantially thermally insulated from the second vapor chamber.

### BACKGROUND

Computer cooling solutions can allow for the removal of waste heat produced by computer equipment, which can help keep such equipment within certain operating temperature limits. Certain computer equipment components, such as integrated circuits, CPUs, chipset, graphics cards, and hard disk drives, are especially susceptible to temporary malfunction or permanent failure if overheated. Such components are often designed to minimize heat generation. Likewise, some computer operating systems are designed to reduce power consumption and related heat generation. Moreover, certain computer systems rely on one or more dedicated cooling solutions to remove unwanted heat. For example, some computer systems rely on fans, heat sinks, and related cooling devices to reduce temperature by actively exhausting hot air.

### BRIEF DESCRIPTION OF DRAWINGS

FIG. 1 depicts a cross-sectional view of a multi-chip module, according to an example.

FIG. 2 depicts a cross-sectional view of a multi-chip module, according to another example.

FIG. 3 depicts a cross-sectional view of a multi-chip module, according to another example.

FIG. 4 depicts a cross-sectional view of a multi-chip module, according to another example.

FIG. 5 depicts a cross-sectional view of a multi-chip module, according to another example.

FIG. 6 depicts a perspective view of a portion of a multi-chip module, according to an example.

FIG. 7 depicts a perspective view of a portion of a multi-chip module, according to an example.

FIG. 8 depicts a perspective view of a portion of a multi-chip module, according to an example.

FIG. 9 depicts a perspective view of a portion of a multi-chip module, according to an example.

FIG. 10 depicts a perspective view of a portion of a multi-chip module, according to an example.

FIG. 11 depicts a perspective view of a portion of a multi-chip module, according to an example.

FIG. 12 depicts a perspective view of a portion of a multi-chip module, according to an example.

FIG. 13 depicts a cross-sectional view of a multi-chip module along a first axis, according to an example.

FIG. 14 depicts a cross-sectional view of the example multi-chip module of FIG. 12 along a second axis that is perpendicular to the first axis of FIG. 13.

FIG. 15 depicts a perspective view of an electronic device according to an example.

### DETAILED DESCRIPTION

The following discussion is directed to various examples of the disclosure. Although one or more of these examples may be preferred, the examples disclosed herein should not be interpreted, or otherwise used, as limiting the scope of the disclosure, including the claims. In addition, the following description has broad application, and the discussion of any example is meant only to be descriptive of that example, and not intended to intimate that the scope of the disclosure, including the claims, is limited to that example. Throughout the present disclosure, the terms “a” and “an” are intended to denote at least one of a particular element. In addition, as used herein, the term “includes” means includes but not limited to, the term “including” means including but not limited to. The term “based on” means based at least in part on.

There are ever-increasing demands for more IT data capacity and faster access for both consumer and enterprise markets. These demands have led to the development of new computing architectures that can more effectively and efficiently manage massive amounts of data. For example, new technologies have emerged that allow for the integration of multiple chips, semiconductor dies, and discrete components into a single package, such as a Multi-Chip Module (MCM). Thermal management is important to successfully implementing such architectures—and especially so in data center environments.

Challenges related to thermal management of such technologies can, for example, include: (1) different temperature limits between component types within a package (e.g., in situations where a memory chip case temperature specification is lower than a temperature specification for a main processor or controller die), (2) situations in which there is a strong thermal cross-talk between different components, and (3) in situations where vertical stacking of components (e.g., memory devices) leads to magnification of hot spot temperatures. Each of these challenges may lead to designs that seek to lower an effective case temperature (T_{c}) specification with an increase in thermal design power levels (Pₜₒₜₐₗ). The above challenges may be amplified in situations where data centers are operated at high inlet air temperatures (Tₐ) or use warm water for waste heat reuse.

Certain implementations of the present disclosure are directed to addressing the above challenges. In some implementations, an MCM is described that includes: (1) a heat sink; (2) a circuit board; (3) a first chip secured to a first location on the circuit board; (4) a first vapor chamber thermally coupled to the first chip to pass heat generated by the first chip to the heat sink; (5) a second chip secured to a second location on the circuit board; and (6) a second vapor chamber thermally coupled to the second chip to pass heat generated by the second chip to the heat sink. In some implementations, a portion of the second vapor chamber is positioned between a portion of the first vapor chamber and the heat sink and the first vapor chamber is substantially thermally insulated from the second vapor chamber.

This arrangement of vapor chambers and other implementations described herein can provide one or more of the following advantages: (1) reduced thermal cross-talk between components, which can reduce a total thermal resistance for the MCM; (2) increased temperature margins for components; (3) improved thermal resistance under the same available physical space; and (4) lower air flow used compared to current cooling solutions, which may result in a reduction on the total product power consumption and related energy savings. Other advantages of implementations presented herein will be apparent upon review of the description and figures.

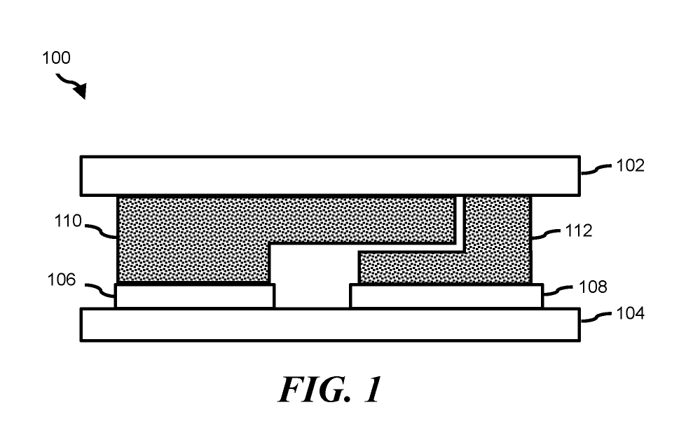

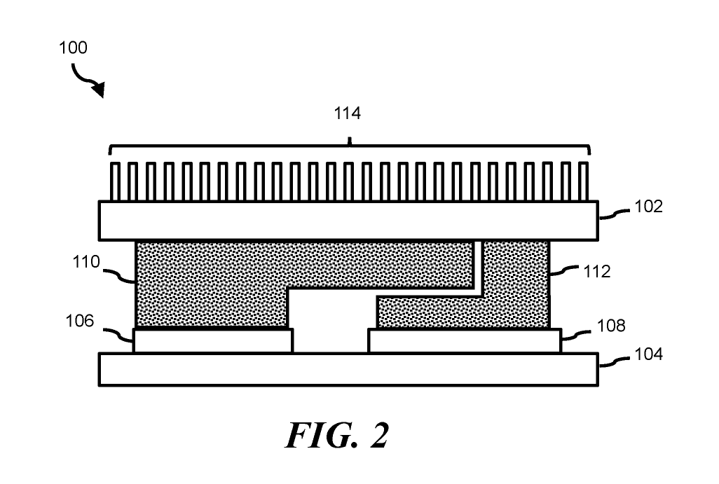

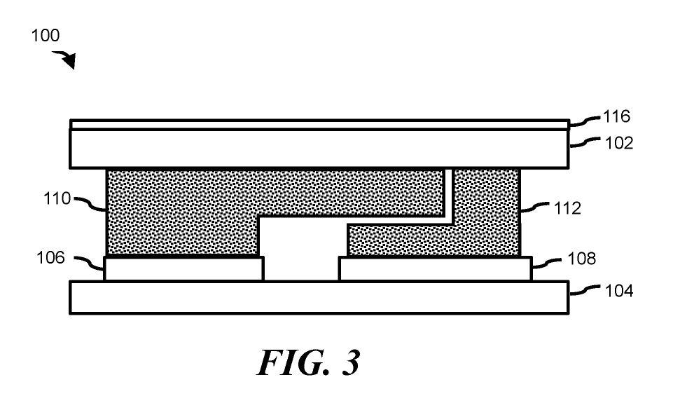

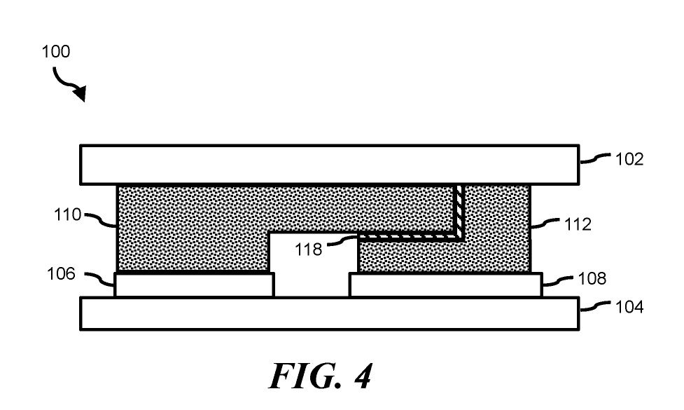

FIGS. 1-4 depicts a cross-sectional view of various examples of multi-chip module (MCM) 100 according to the present disclosure. In particular, FIG. 1 depicts MCM 100 including a heat sink 102, a circuit board 104, a first chip 106, a second chip 108, a first vapor chamber 110 and a second vapor chamber 112; FIG. 2 depicts MCM 100 of FIG. 1 further including a heat sink 102; FIG. 3 depicts MCM 100 of FIG. 1 further including an Integrated Heat Spreader (IHS) 116; and FIG. 4 depicts MCM 100 of FIG. 1 further including an insulating between first vapor chamber 110 and second vapor chamber 112. Each of these implementations will be described in further detail below.

As provided herein, certain implementations of the present disclosure are directed to designs that can reduce thermal-cross talk between components of MCM 100 (e.g., first chip 106 and second chip 108). The term “Multi-Chip Module” or “MCM” as used herein can, for example, refer generally to an electronic assembly where multiple integrated circuits, semiconductor dies, and/or other discrete components are integrated, usually onto a unifying substrate. Such an MCM can, for example, be treated as if it were a single component (e.g., as though it were a larger Integrated Circuit (IC)). Suitable electronic assemblies can, for example, refer to packages including conductor terminals or “pins”). In suitable contexts, the term “MCM” can also refer to related industry terms, such as “hybrid” or “hybrid integrated circuit.” MCMs can, for example, be used with certain processors, graphic processing units (GPUs), non-volatile memory DIMM devices, gaming consoles, portable storage devices (e.g., USB drives, memory cards, etc.), etc. In some implementations, an MCM may rely on a different layout architecture, which can depend on its application and physical limitations. Such layout architectures can, for example, be a 2D architecture (e.g., tiled horizontally or stacked vertically) or 2.5D/3D architectures (e.g., tiled horizontally and stacked vertically).

It is appreciated that one or more aspects described herein can be applied to other suitable electronic components or assemblies other than MCMs. For example, in some implementations, aspects can be applied to a heat generating component that is not in the form of a “chip.” In such an implementation, first vapor chamber 110 and second vapor chamber 112 can comprise a vapor chamber system for cooling heat generating components of circuit board 104. In some implementations, first vapor chamber 110 is to pass heat generated by a first heat generating component of circuit board 104 to heat sink 102. In such an implementation, second vapor chamber 112 is to pass heat generated by a second heat generating component of circuit board 104 to heat sink 102. In some implementation of such a system, a portion of second vapor chamber 112 is positioned between a portion of first vapor chamber 110 and heat sink 102 and the portion of second vapor chamber 112 is thermally insulated from the portion of first vapor chamber 110.

As provided above, MCM 100 includes a heat sink 102 that receives heat generated by first chip 106 via first vapor chamber 110 and receives heat generated by second chip 108 via second vapor chamber 112. The term “heat sink” as used herein can, for example, refer to a passive heat exchanger that transfers heat generated by an electronic device to a cooling medium (e.g., air or a liquid coolant), where it is dissipated away from the device. This can, for example, allow regulation of the device's temperature. One or more heat sinks of the present disclosure can be designed to maximize a surface area in contact with the cooling medium surrounding it. One or more heat sinks of the present disclosure can be made of copper, aluminum, and/or another suitable material.

In some implementations, heat sink 102 can, for example, include heat sink fins. FIG. 2, for example, depicts an MCM 100 that includes example heat sink fins 114. Fins 114 can be in any suitable form or shape. For example, in some implementations, fins 114 can be in the form of a pin fin heat sink with pins extending from a base. Such pins can, for example, be cylindrical, elliptical or square. In some implementations, fins 114 can be in the form of a straight fin. Such a fin can run an entire (or portion) of a length of the heat sink. It is appreciated that other shapes and forms of heat sinks can be applied, such as a cross-cut heat sink.

In some implementations, such as the implementation depicted in FIG. 2, heat sink 102 can, for example, include an Integrated Heat Spreader (IHS). As used herein, the term “heat spreader” can, for example, refer to a heat exchanger that moves heat between a heat source (e.g., first chip 106) and a secondary heat exchanger (e.g., heat sink 102) whose surface area and geometry are more favorable than the heat source. In some implementations, heat spreader 116 can be in the form of a suitably dimensioned thin plate. Heat spreader 116 can, for example, be made of copper or another suitable material (e.g., a material having a suitable high thermal conductivity). The use of such a heat spreader can, for example, allow heat to be spread out so that the secondary heat exchanger may be more fully utilized, which can allow for an increased heat capacity of the total assembly to allow more effective radiation of heat.

As provided above, MCM 100 includes a circuit board 104 to which the first chip 106 and second chip 108 secured at respective locations on circuit board 104. As used herein, the term “circuit board” can, for example, refer to a printed circuit board (PCB) that mechanically supports and electrically connects electronic components using conductive tracks, pads and other features. Such a circuit board can, for example, rely on copper sheet etchings that are laminated onto a non-conductive substrate. Components (e.g. capacitors, resistors or active devices) can, for example, be soldered on such a PCB. It is appreciated that certain suitable PCBs can, for example, include components embedded in the substrate.

The term “chip” as used herein can, for example, refer to an integrated circuit or monolithic integrated circuit and can also be referred to as an “IC” or “microchip”. Such a chip can, for example, be in the form of a set of electronic circuits on a small flat piece of semiconductor material (e.g., silicon). First chip 106 can, for example, be in the form of a Central Processing Unit (CPU) and second chip 108 can, for example, be in the form of a memory chip. As used herein, the terms “Central Processing Unit’ or “CPU” can, for example, refer to electronic circuitry within a computer that carries out instructions of a computer program by performing arithmetic, logical, control and input/output (I/O) operations specified by the instructions. The terms can, for example, refer to a processing unit and control unit (CU) as distinguished from main memory and I/O circuitry. Such a CPU can, for example, be in the form of a microprocessor on a single integrated circuit (IC) chip. It is appreciated that an IC chip that contains a CPU may also contain memory, peripheral interfaces, and other components of a computer. Such an integrated device can, for example, be referred to as a microcontrollers or systems on a chip (SoC), or MCM. As used herein, the term “memory chip” can, for example, refer to an IC used to store data or process code. The IC can, for example, include capacitors and transistors and can, for example, hold memory temporarily (e.g., through random access memory (RAM) or permanently (e.g., through read only memory (ROM)).

As provided above, MCM 100 includes a first vapor chamber 110 that is thermally coupled to first chip 106 to pass heat generated by first chip 106 to heat sink 102. MCM 100 also includes a second vapor chamber 112 of MCM 100 that is thermally coupled to second chip 108 to pass heat generated by second chip 108 to heat sink 102. The term “vapor chamber” as used herein can, for example, refer to an arrangement that attempts to maximize the use of surface area available from a heat sink. In certain vapor chambers, a liquid (e.g., water) can evaporate on a “powered component side” of the chamber. The resulting vapor can spread uniformly on the other side of the chamber, which may be referred to as the “condenser side” of the chamber. The vapor can condense to water on the condenser side, which may be self-recirculated under surface tension force within the vapor chamber.

In some implementations, first vapor chamber 110 can include a suitable first type of liquid or gas selected to accommodate thermal characteristics of first chip 106. In some implementations, liquid within first vapor chamber 110 is water, methanol, or acetone. In some implementations, second vapor chamber 112 can include a suitable second type of liquid or gas selected to accommodate different thermal characteristics of second chip 108. It is appreciated that in some implementations, a liquid or gas of first vapor chamber 110 may be the same as a liquid or gas of second vapor chamber 112. In some implementations, a volume of first vapor chamber 110 is sized to accommodate thermal characteristics of first chip 106. Likewise, in some implementations, a volume of second vapor chamber 112 is sized to accommodate different thermal characteristics of second chip 108. It is appreciated that in some implementations, the volume of first vapor chamber 110 is the same as the volume of second vapor chamber 112.

As depicted in the example implementation of FIG. 1, a portion of second vapor chamber 112 is positioned between a portion of first vapor chamber 110 and heat sink 102. In this implementation, first vapor chamber 110 is substantially thermally insulated from second vapor chamber 112. Such an implementation can, for example, reduce thermal cross-talk between components. As used herein, the term “thermal cross-talk” can, for example, refer to the sharing of common heat transfer paths between electronic devices. This can, for example, result in a thermal interaction between devices in which heat generated from higher power level devices can affect temperature conditions of a lower power level devices.

In some implementations, MCM 100 includes an insulation layer between first vapor chamber 110 and second vapor chamber 112 to substantially thermally insulate first vapor chamber 110 from second vapor chamber 112. FIG. 4 depicts an example MCM 100 that includes an insulation layer 118. The insulation layer can, for example, be in the form of a thermally insulating material designed for electronic components. In some implementations, the material can be a silica layer, calcium-magnesium silicate layer, or another suitable layer of material. The insulation layer can be in the form of a flat sheet, or other suitable shape to provide insulation between first vapor chamber 110 and second vapor chamber 112.

Various example implementations for the present disclosure will now be described. It is appreciated that these examples may include or refer to certain aspects of other implementations described herein (and vice-versa), but are not intended to be limiting towards other implementations described herein. Moreover, it is appreciated that certain aspects of these implementations may be applied to other implementations described herein.

In some implementations, an evaporative cooling solution can address thermal challenges of MCMs (e.g., MCM 100) and similar electronic equipment. The solution can, for example, incorporate the design of multiple vapor cavities to redirect heat generated by electronic components into specific areas for controlled heat extraction. This can, for example, result in improved thermal management of devices inside multi-chip packages by reducing thermal cross-talk between components and may further result in a reduction of the effective thermal resistance obtain for this type of cooling solution, which has the potential for energy savings by lowering the power consumption required to cool these devices.

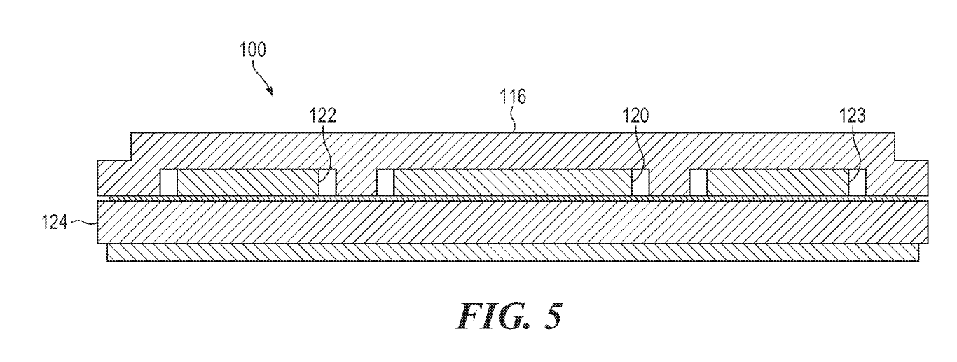

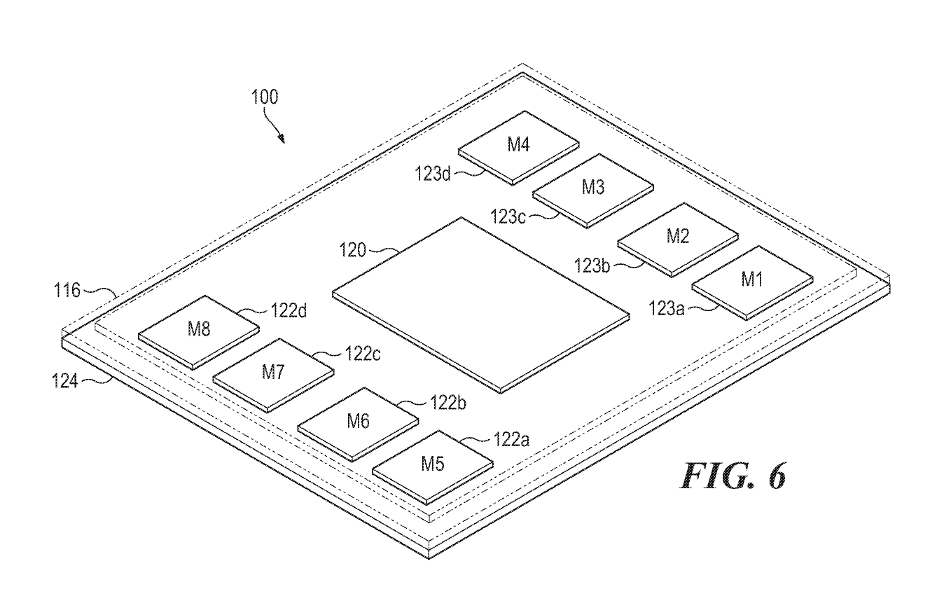

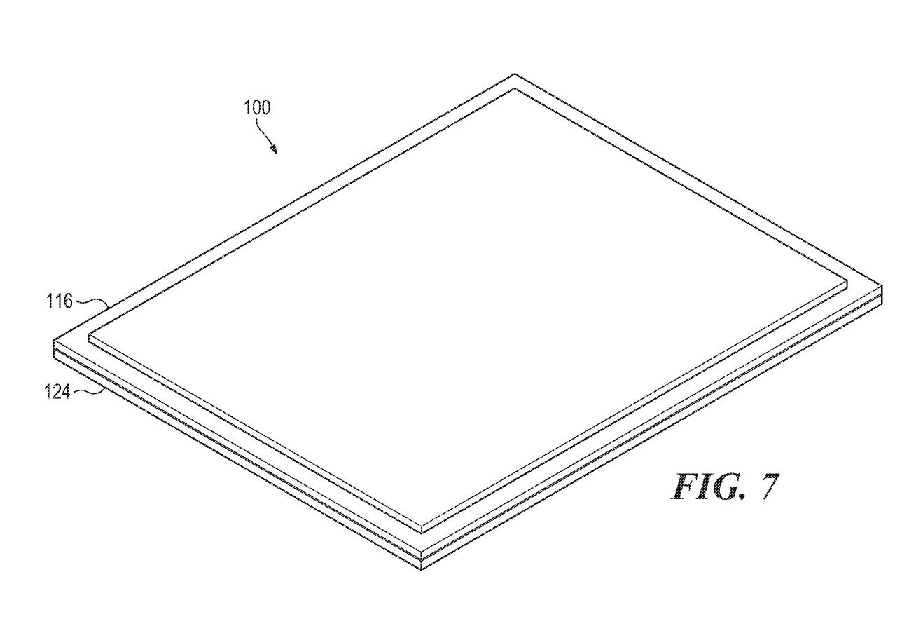

When certain electronic devices are positioned close together such that they share common heat transfer paths there is a thermal interaction between them where the heat generated from the higher power level devices affects the temperature conditions of lowered-power ones. FIGS. 5-7 show an MCM 100 comprising of a main CPU chip 120 at the middle of the module substrate surrounded by two group of memory chips 122 (more specifically, chips 122a, 122b, 122c, 122d) and 123 (more specifically, chips 123a, 123b, 123c, and 123d) on two sides. A solid metal cover that acts as an integrated heat spreader 116 is placed over CPU chip 120 and memory chips 122, 123, 125, and 127 to protect them and serves as a single attachment surface to the cooling solution placed over it. The MCM power map consist of a main heat source coming from CPU chip 120 (higher power) with multiple heat sources coming from each memory chip 122, 123, 125, and 127 (lower power). CPU chip 120 and memory chips 122, 123, 125, and 127 are connected thermally by two main paths: the package substrate 124 and the heat spreader 116. Each device case temperature is defined as the temperature measured at the location on the surface of the heat spreader 116 above each component die hot spot. We can then describe the thermal cross-talk between the CPU and memory chips by using the following relationship:

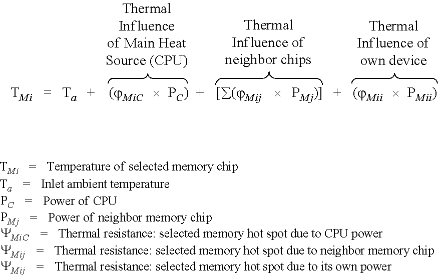

We can observe from the equation above that the final temperature of each device (T_{Mi}) can be expressed as the ambient temperature (Tₐ) plus the temperature contribution of each of the neighbor devices and itself. This contribution can be referred to as “thermal influence”. For this test case, we can arrange this thermal influence into three main components: 1) the thermal influence of the CPU (main heat source), 2) the thermal influence of all the neighbor memory chips, and 3) its own thermal influence.

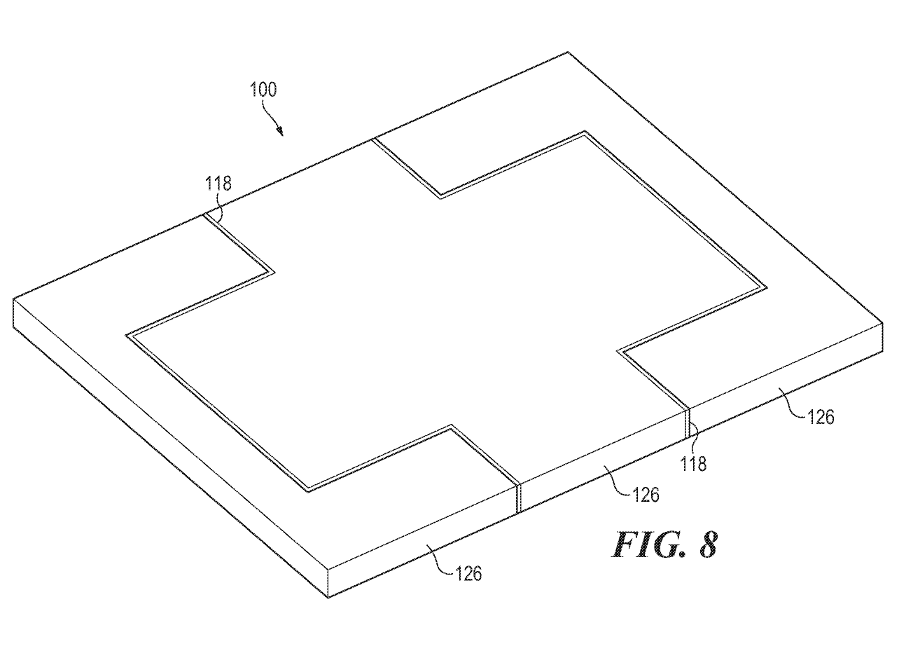

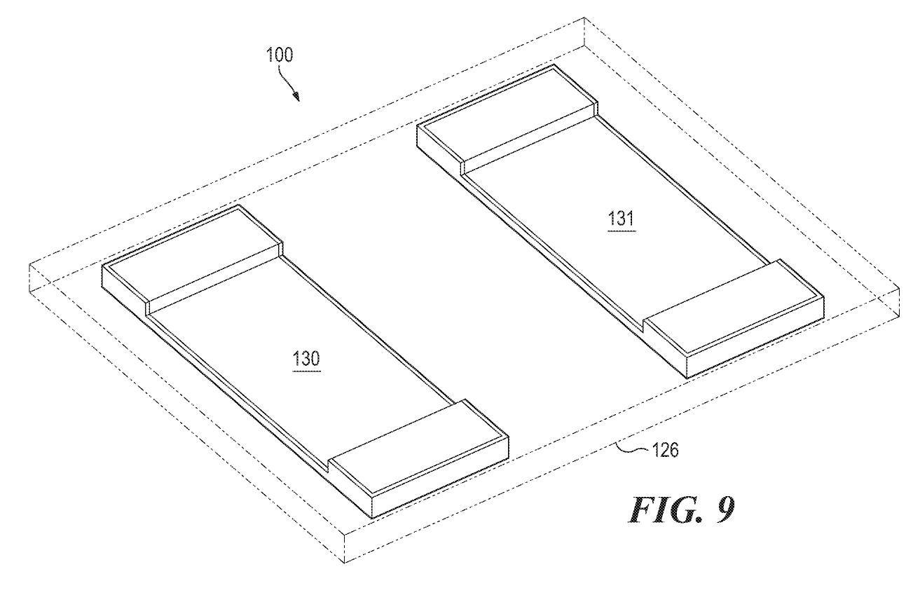

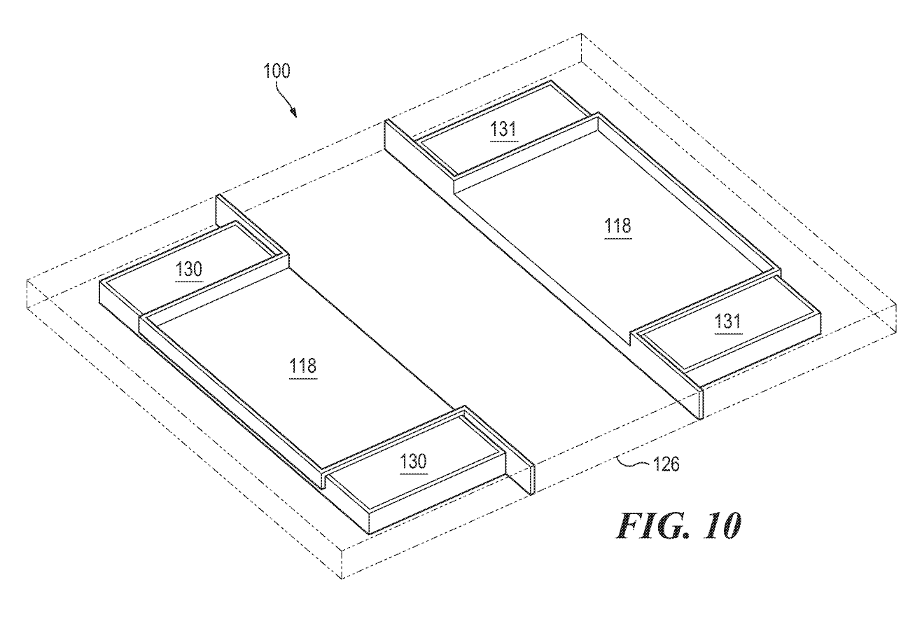

We then apply this “cross-talk” methodology to investigate how the cooling solutions available in the market perform for MCMs. Multiple thermal simulations, using computational fluid dynamic (CFD) modeling, were performed with a heat sink placed on top of the test case MCM (see FIGS. 8 and 9). Two heat sink versions were evaluated: 1) with a solid metal base, and 2) with a typical vapor chamber base. Heat was extracted from each of the cooling solutions by flowing 20 cubic feet per minute (CFM) of air at 40° C. After we completed the CFD simulations we observed that when using a solid base heat sink the thermal influence of the CPU on the memory chips is 82% (average), the thermal influence of grouping all the memory chips is 12% and the thermal influence of each memory chip is only 6% (See FIG. 10). We will focus then our analysis and cooling solution comparison on the impact the CPU has on the memory chips (CPU thermal influence) in addition to the case temperature recorded on each device.

When a typical vapor chamber (VC) device is inserted as part of heat sink base we can obtain a significant case temperature reduction on most of the chips (and in particular the CPU) as shown in table 1 below:

TABLE 1
Case Temperature Results (Solid vs Typical VC Heat sink)

| | Case Temperature (° C.) | | Difference |
|---|---|---|---|
| MCM Chip | Solid | Typical VC | (VC Type − Solid) |
| M1 | 66.9 | 65.5 | −2% |
| M2 | 68.2 | 65.6 | −4% |
| M3 | 68.2 | 65.6 | −4% |
| M4 | 66.8 | 65.5 | −2% |
| M5 | 61.6 | 65.2 | 6% |
| M6 | 62.8 | 65.3 | 4% |
| M7 | 62.8 | 65.3 | 4% |
| M8 | 61.7 | 65.2 | 6% |
| CPU | 79.8 | 74.0 | −7% |

This can be achieved due to the benefits of the vapor chamber to improve the heat spreading across the heat sink and maximize the utilization of the surface area available. However, because of this reduction in the spreading resistance, some of the memory chips (M5 to M8) experience an increase in temperature which relates to an increase in the thermal influence of the CPU as shown in the table below. In other words, the thermal cross-talk between components on a MCM increases when current vapor chamber devices are used.

TABLE 2
CPU Thermal Influence Results (Solid vs Typical VC Heat sink)

| | CPU Thermal Influence | | Difference |
|---|---|---|---|
| MCM Chip | Solid | Typical VC | (VC Type − Solid) |
| M1 | 82% | 82% | 0% |
| M2 | 83% | 82% | 0% |
| M3 | 83% | 82% | 0% |
| M4 | 82% | 82% | 0% |
| M5 | 81% | 82% | 1% |
| M6 | 81% | 82% | 1% |
| M7 | 81% | 82% | 1% |
| M8 | 81% | 82% | 1% |

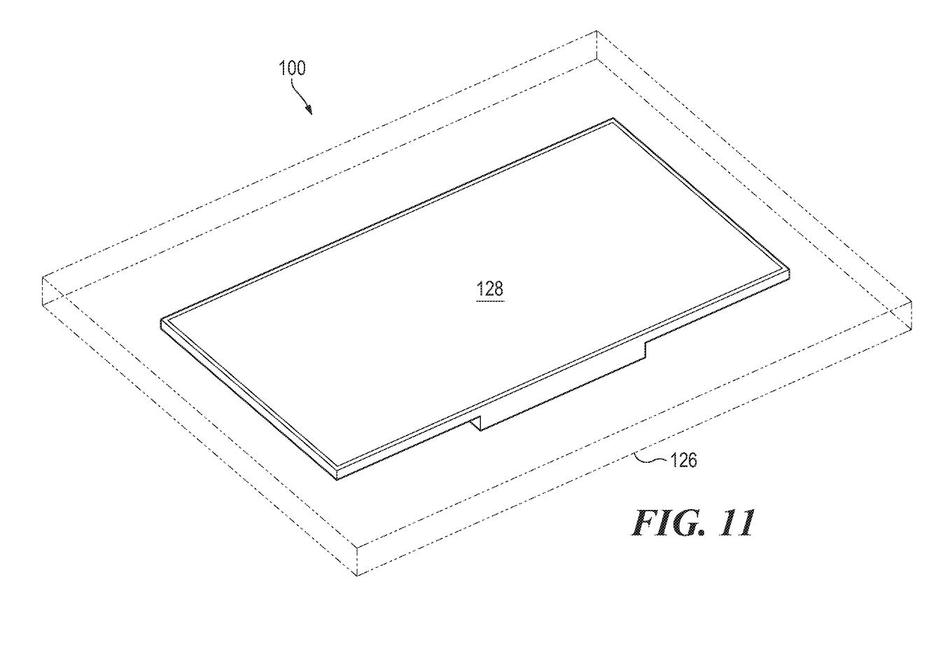

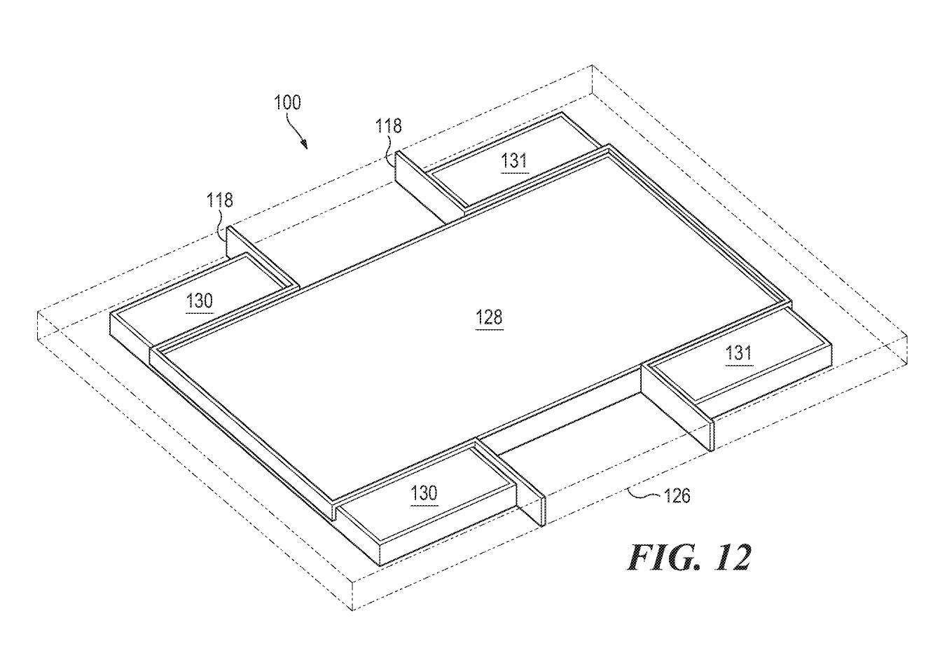

As depicted in FIGS. 8-12, certain implementations of the present disclosure are directed to a new cooling device that includes a metal outer shell 126 that makes contact with MCM 100 on the bottom side and makes contact with an array of fins attached at the top side. Inside outer shell 126 is an arrangement of vapor cavities, each one designed to transfer heat from specific components to localized fin sections. Insulation layers 118 between vapor cavities are included to help reduce thermal cross-talk. In this implementation, three vapor cavities (128, 130, and 131) and are created, two for respective memory chip clusters 122 and 123 and one for the CPU chip 120.

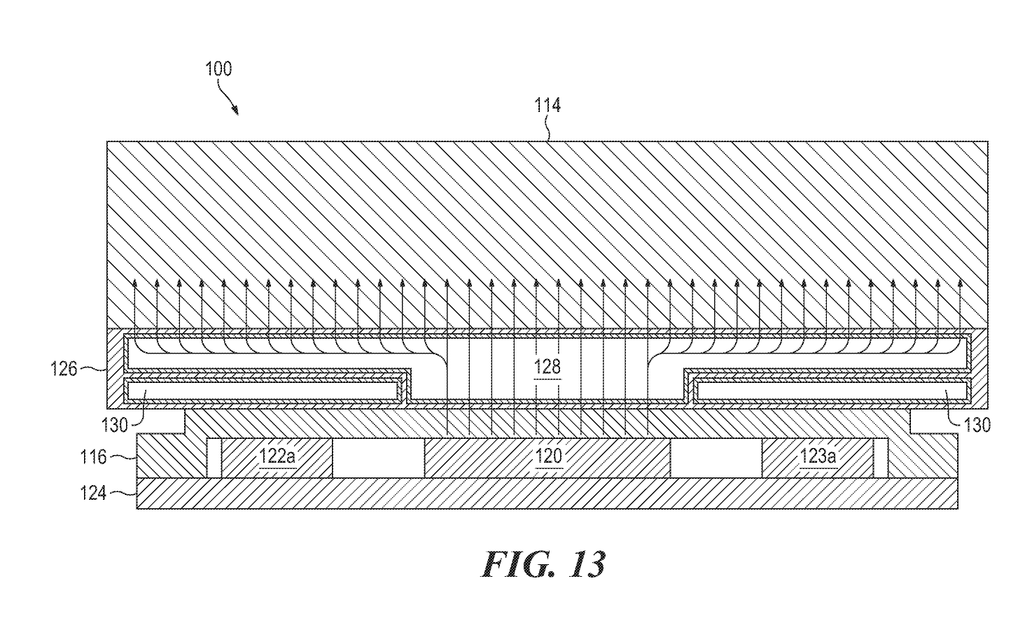

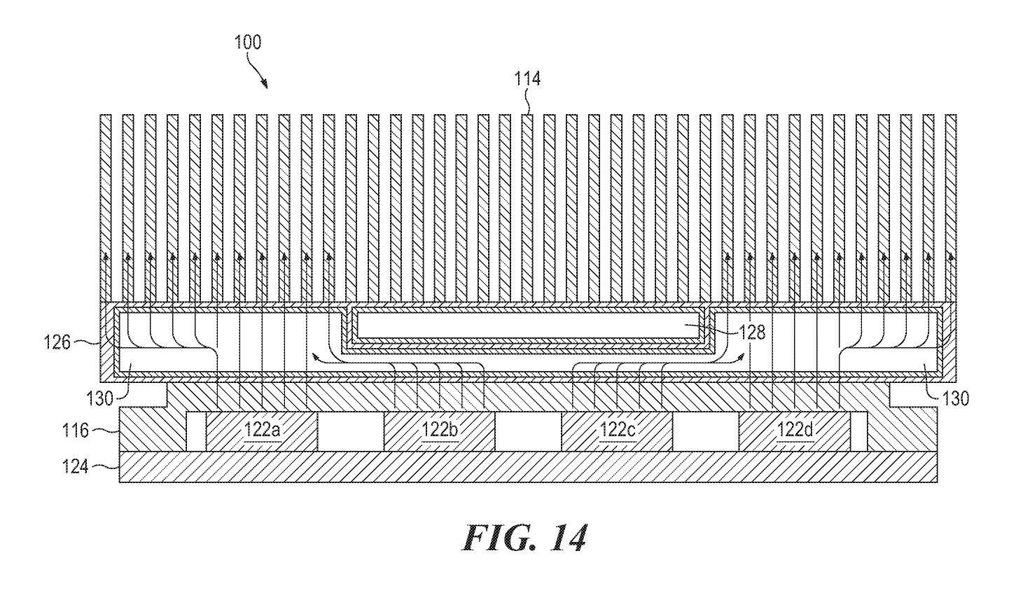

FIGS. 13 and 14 depicts cross-sectional views of an example MCM 100. In particular, FIG. 13 depicts a first cross-sectional view along a first axis of MCM 100 and FIG. 14 depicts a second cross-sectional view along a second axis of MCM 100 that is perpendicular to the first axis of MCM 100. During operation of the MCM heat generated from CPU chip 120 will be manage by the CPU inner vapor cavity 128, redirecting it over the memory vapor cavity 130 into the fins above. This reduces the CPU thermal influence to the memory chips, which then results in lower case temperature levels. The heat generated by the memory devices is then managed by their respective vapor cavities, which then redirect it into different fins sections above.

CFD simulations were performed based on this new cooling solution and the results were compared with results of other solutions including a solid base solution and a single vapor chamber solution. The results show a dramatic reduction in the thermal influence of the CPU on the memory devices (see Table 3 below) and a reduction in the final temperature of all the devices inside the MCM (see Table 4 below). As demonstrated by these experimental results, the solutions of the present disclosure offer an improved cooling solution for multi-chip modules due to its ability to reduce the thermal cross-talk between devices in the module.

TABLE 3
CFD Results - CPU Thermal Influence

| | Thermal Influence CPU | | | Difference (VC Type − Solid) | |
|---|---|---|---|---|---|
| Device | Solid | Typical VC | 3D VC | Typical VC | 3D VC |
| M1 | 82% | 82% | 76% | 0% | −7% |
| M2 | 83% | 82% | 76% | 0% | −7% |
| M3 | 83% | 82% | 76% | 0% | −7% |
| M4 | 82% | 82% | 76% | 0% | −7% |
| M5 | 81% | 82% | 72% | 1% | −9% |
| M6 | 81% | 82% | 72% | 1% | −9% |
| M7 | 81% | 82% | 72% | 1% | −9% |
| M8 | 81% | 82% | 72% | 1% | −9% |

TABLE 4
CFD Results - Case Temperature

| | Case Temperature (° C.) | | | Difference (VC Type − Solid) | |
|---|---|---|---|---|---|
| Device | Solid | Typical VC | 3D VC | Typical VC | 3D VC |
| M1 | 66.9 | 65.5 | 64.9 | −2% | −3% |
| M2 | 68.2 | 65.6 | 65.0 | −4% | −5% |
| M3 | 68.2 | 65.6 | 65.0 | −4% | −5% |
| M4 | 66.8 | 65.5 | 64.9 | −2% | −3% |
| M5 | 61.6 | 65.2 | 58.9 | 6% | −5% |
| M6 | 62.8 | 65.3 | 58.9 | 4% | −6% |
| M7 | 62.8 | 65.3 | 58.9 | 4% | −6% |
| M8 | 61.7 | 65.2 | 58.9 | 6% | −5% |
| CPU | 79.8 | 74.0 | 75.3 | −7% | −6% |

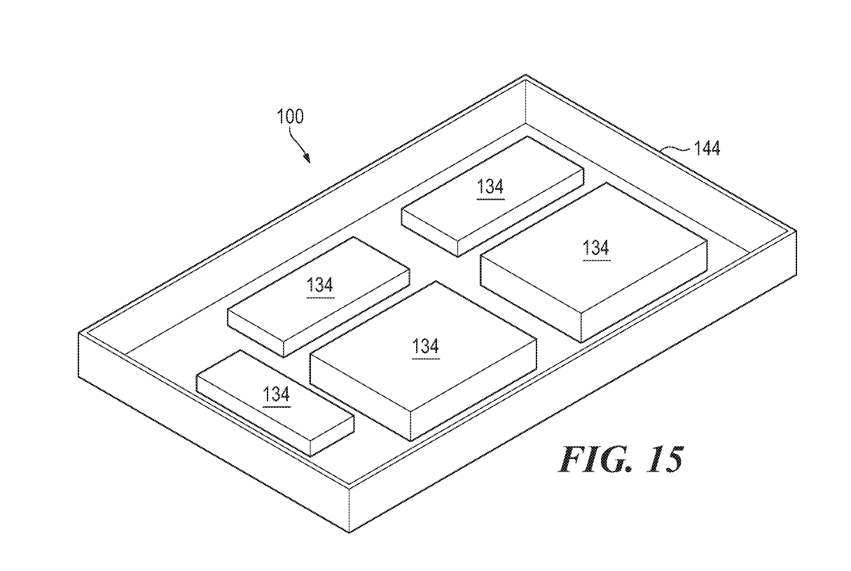

FIG. 15 is a diagram of an example electronic device 132 according to the present disclosure. For illustration, various aspects of other implementations described herein are referred to with respect to device 132 of FIG. 15 and common reference numbers are used between the various figures. It is appreciated that aspects of device 132 of FIG. 15 can be implemented in other implementations described herein and vice versa.

Electronic device 132 includes multiple packages 134 having a first heat generating component 136, a second heat generating component 138, a first sealed vapor chamber 140, and a second sealed vapor chamber 142. The interior of packages 134 are not depicted in FIG. 15 but various examples of such an interior are otherwise depicted herein. Electronic device 132 can, for example, refer generally to any suitable electronic equipment. The equipment can, for example, be in the form of data center equipment, such as a processing, storage, or networking nodes. For example, in some implementations, electronic device 132 is in the form of a suitable rack or blade server, storage array, power supply, network switch, and/or any combination thereof etc. It is also appreciated that electronic device 132 can, for example, be in the form of a personal computing device, such as a personal computer, laptop, mobile device, tablet, etc. In the implementation depicts in FIG. 15, electronic device 132 includes a housing 144 that houses multiple heat generating components within packages 134.

First sealed vapor chamber 140 can, for example, be partially filled with a first liquid, the first liquid to vaporize in response to heat generated by first heat generating component 136. Likewise, second sealed vapor chamber 142 can, for example, be partially filled with a second liquid, the second liquid to vaporize in response to heat generated by second heat generating component 138. In this implementation, first vapor chamber 110 partially overlaps second vapor chamber 112 and is sized to accommodate an expected thermal load of first heat generating component 136 that is larger than an expected thermal load of second heat generating component 138. Such a vapor chamber system can, for example, include an insulating layer (e.g., layer 118) sandwiched between first vapor chamber 110 and second vapor chamber 112 to thermally insulate first vapor chamber 110 from second vapor chamber 112.

While certain implementations have been shown and described above, various changes in form and details may be made. For example, some features that have been described in relation to one implementation and/or process can be related to other implementations. In other words, processes, features, components, and/or properties described in relation to one implementation can be useful in other implementations. Furthermore, it should be appreciated that the systems and methods described herein can include various combinations and/or sub-combinations of the components and/or features of the different implementations described. Thus, features described with reference to one or more implementations can be combined with other implementations described herein. As used herein, “a” or “a number of” something can refer to one or more such things. For example, “a number of widgets” can refer to one or more widgets.

What is claimed is:

1. A multiple chip module (MCM) comprising:
a heat sink;
a circuit board;
a first chip secured to a first location on the circuit board;
a first vapor chamber thermally coupled to the first chip to pass heat generated by the first chip to the heat sink;
a second chip secured to a second location on the circuit board; and
a second vapor chamber thermally coupled to the second chip to pass heat generated by the second chip to the heat sink,
wherein a portion of the second vapor chamber is positioned between a portion of the first vapor chamber and the heat sink, and
wherein the first vapor chamber is substantially thermally insulated from the second vapor chamber.

2. The MCM of claim 1, wherein the heat sink includes heat sink fins.

3. The MCM of claim 1, wherein the heat sink includes an Integrated Heat Spreader (IHS).

4. The MCM of claim 1, wherein the first chip is a Central Processing Unit (CPU) and the second chip is a memory chip.

5. The MCM of claim 1, comprising:
an insulation layer between the first and second vapor chambers to substantially thermally insulate the first vapor chamber from the second vapor chamber.

6. The MCM of claim 1, wherein the insulation layer is made of a thermally insulating material.

7. The MCM of claim 1, wherein the first vapor chamber includes a first type of liquid or gas selected to accommodate thermal characteristics of the first chip and the second vapor chamber includes a second type of liquid or gas selected to accommodate different thermal characteristics of the second chip.

8. The MCM of claim 1, wherein a volume of the first vapor chamber is sized to accommodate thermal characteristics of the first chip and a volume of the second vapor chamber is sized to accommodate different thermal characteristics of the second chip.

9. The MCM of claim 1, further comprising:
a third chip secured to a third location on the circuit board,
wherein the first vapor chamber is to pass heat generated by both the first chip and the third chip to the heat sink.

10. The MCM of claim 9, wherein the first chip is a memory chip, the second chip is a Central Processing Unit (CPU) chip, and the third chip is a memory chip.

11. A vapor chamber system for cooling heat generating components of a circuit board, the system comprising:
a first vapor chamber to pass heat generated by a first heat generating component of a circuit board to a heat sink; and
a second vapor chamber to pass heat generated by a second heat generating component of a circuit board to the heat sink,
wherein a portion of the second vapor chamber is positioned between a portion of the first vapor chamber and the heat sink.

12. The vapor chamber system of claim 11, wherein the portion of the second vapor chamber is thermally insulated from the portion of the first vapor chamber.

13. An electronic device comprising:
a first heat generating component;
a second heat generating component;
a first sealed vapor chamber partially filled with a first liquid, the first liquid to vaporize in response to heat generated by the first heat generating component; and
a second sealed vapor chamber partially filled with a second liquid, the second liquid to vaporize in response to heat generated by the second heat generating component,
wherein the first vapor chamber partially overlaps the second vapor chamber and is sized to accommodate an expected thermal load of the first heat generating component that is larger than an expected thermal load of the second heat generating component.

14. The electronic device of claim 14, further comprising:
an insulating layer sandwiched between the first vapor chamber and the second vapor chamber to thermally insulate the first vapor chamber from the second vapor chamber.

15. The electronic device of claim 13, wherein the electronic device is a server, the first heat generating component is a Central Processing Unit (CPU) chip, and the second heat generating component is a memory chip.
